(19) United States
(12) Patent Application Publication
(10) Pub. No.: US 2017/0053593 A1
(43) Pub. Date: Feb. 23, 2017

(54) Amoled Panel, Manufacturing Method Thereof, and Display Device

(71) Applicant: EverDisplay Optronics (Shanghai) Limited, Shanghai (CN)

(72) Inventor: Yen Chih Cheng, Shanghai (CN)

(21) Appl. No.: 15/238,594

(22) Filed: Aug. 16, 2016

(30) Foreign Application Priority Data
Aug. 20, 2015 (CN) 201510515955.5

(51) Int. Cl. G09G 3/3225; H01L 21/66; H01L 51/56

(52) U.S. Cl. CPC G09G 3/3225; H01L 51/56; H01L 22/12; G09G 2330/028

(57) ABSTRACT

The application relates to the field of semiconductor technology, more particularly, to an AMOLED panel, a manufacturing method thereof, and a display device. By a disposed driving power structure and a compensating power structure on the panel, difference generated by IR drop in different positions of the panel can be compensated by the compensating power structure, thus the optical homogeneity of the AMOLED panel is increased, and the display performance of the AMOLED panel is improved.

### CROSS-REFERENCE TO RELATED APPLICATIONS

The present application claims priority to and the benefit of Chinese Patent Application No. CN 201510515955.5, filed on Aug. 20, 2015, the entire content of which is incorporated herein by reference.

### BACKGROUND OF THE APPLICATION

Field of the Application

The application relates to the field of semiconductor technology, more particularly, to an AMOLED panel, a manufacturing method thereof, and a display device.

Description of the Related Art

At present, when making the circuit layout of the AMOLED (Active Matrix/Organic Light Emitting Diode), we configure the voltage source potential (ELVDD) to a single electric potential, as shown in FIG. 1. With the increasing of panel size, the IR drop between different areas of the panel differs greatly, thus the optical characteristics of different positions of the panel are inconsistent, and the display quality of the panel is reduced greatly.

For example, as shown in FIG. 2, in present AMOLED circuit layout, the voltage source potential (ELVDD) transmits from the Flexible Printed Circuit (FPC) under the panel to the Active Area (AA) through a DataLine (DL), due to the existence of IR drop, the brightness of top area of the panel is darker than other areas, and the brightness of bottom area of the panel adjacent to ELVDD is brighter than other areas, thus the display homogeneity of the entire panel is very poor.

### SUMMARY OF THE APPLICATION

In view of the above-mentioned problems, the application provides an AMOLED panel, a manufacturing method thereof, and a display device.

An AMOLED panel, comprising:
an AMOLED body, provided with a front area and a terminal area opposite to the front area;
a plurality of optical elements disposed above the AMOLED body between the front area and the terminal area; and
a compensating power structure disposed above the AMOLED body in the front area;
wherein the compensating power structure electrically connects to each of the optical elements respectively, to be configured to improve optical homogeneity of the AMOLED panel by compensating a voltage to the optical elements.

The above-mentioned AMOLED panel, further comprises:
a driving power structure disposed above the AMOLED body;
data transmission lines, disposed above the AMOLED body, and the driving power structure connects to the optical elements through the data transmission lines, to drive each of the optical elements to operate;
wherein a voltage drop is generated in the data transmission lines when the driving power structure drives the optical elements to operate, the compensating power structure compensate the voltage drop, to improve optical homogeneity of the AMOLED panel.

The above-mentioned AMOLED panel, wherein the optical elements have a rated voltage;
the compensating voltages, which are generated by the compensating power structure and provided to the optical elements, increase gradually along the direction extending from the front area to the terminal area, so that each operating voltage of the optical elements reaches the rated voltage.

The above-mentioned AMOLED panel, wherein the AMOLED body is also provided with an active area, the compensating power structures electrically connects to each of the optical elements respectively in condition that the metal wire encircles the active area.

The above-mentioned AMOLED panel, wherein the AMOLED body is also provided with a gate power structure, the gate power structure electrically connects to the gate of each of the optical elements respectively.

The above-mentioned AMOLED panel, wherein the AMOLED body is also provided with a flexible printed circuit, the flexible printed circuit is provided with a driving power connected to the driving power structure, a compensating power connected to the compensating power structure and a gate power connected to the gate power structure.

A display device comprises the above-mentioned AMOLED panel.

A method for manufacturing an AMOLED panel, comprising:
providing an AMOLED body with a plurality of optical elements, the AMOLED body comprises a front area and a terminal area opposite to the front area;
disposing a driving power structure in the front area of the AMOLED body, the driving power structure electrically connects to each of the optical elements respectively, to drive the optical elements to emit light; and
disposing at least one compensating power structure in the terminal area of the AMOLED body, the compensating power structure electrically connects to each of the optical elements respectively, to compensate a potential to the optical elements.

The above-mentioned method, wherein further comprises:
measuring optical characteristics of each area of the AMOLED body, establishing an optical characteristics data of each area of the panel, to compensate a potential according to the optical characteristics data of each area of the AMOLED panel.

The above-mentioned method, wherein the optical characteristics comprise at least one of the following characteristics: brightness, hue and chroma.

In conclusion, the application discloses an AMOLED panel, a manufacturing method thereof, and a display device. By disposing driving power structure and compensating power structure on the panel, the compensating power structure can compensates the difference generated by IR drop in different positions of the panel, thus the optical homogeneity of the AMOLED panel is increased, and the display quality of the AMOLED panel is greatly improved.

### BRIEF DESCRIPTIONS OF THE DRAWINGS

The accompanying drawings, together with the specification, illustrate exemplary embodiments of the present disclosure, and, together with the description, serve to explain the principles of the present application.

FIG. 1 is a diagram of operating principle of the AMOLED panel in the prior art.

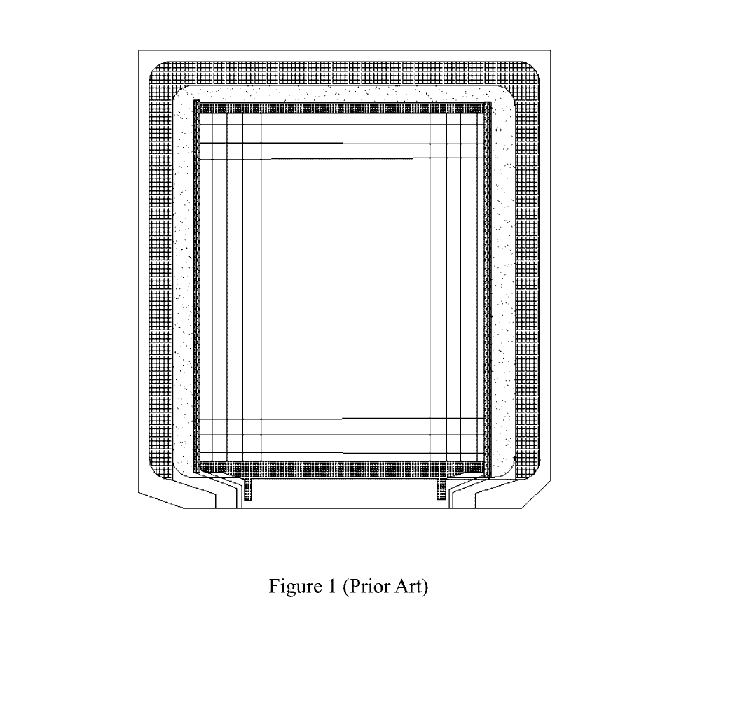

FIG. 2 is a diagram of brightness of different areas of the AMOLED panel in the prior art.

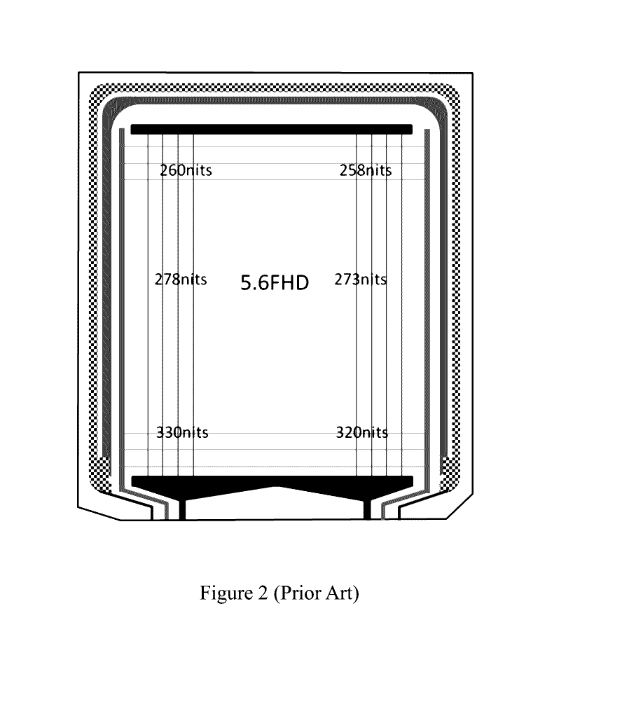

FIG. 3 is a structural diagram of an AMOLED panel of the present application.

### DETAILED DESCRIPTION

The present application will now be described more fully hereinafter with reference to the accompanying drawings, in which exemplary embodiments of the application are shown. This application may, however, be embodied in many different forms and should not be construed as limited to the embodiments set forth herein. Rather, these embodiments are provided so that this disclosure will be thorough and complete, and will fully convey the scope of the application to those skilled in the art. Like reference numerals refer to like elements throughout.

The terminology used herein is for the purpose of describing particular embodiments only and is not intended to be limiting of the application. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this application belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

As used herein, the term “plurality” means a number greater than one.

Hereinafter, certain exemplary embodiments according to the present disclosure will be described with reference to the accompanying drawings.

The idea of the application is to configure the voltage source potential of the AMOLED panel circuit as multiple potentials according to different areas, and to make the flexible printed circuit encircle the active area through data lines and send signals to different areas. Since the voltage source potential are multiple potentials, by compensating the difference of IR drop between different areas, we can make the optical characteristics of different areas of the panel consistent, thus the display quality of the panel is greatly improved.

Based on traditional AMOLED panel structure, by disposing at least two potentials in different areas of the panel, to compensate a IR drop of the panel, and improve the optical homogeneity of the panel, therefore the application designs an AMOLED panel, comprising:
an AMOLED body, the AMOLED body has a front area and a terminal area opposite to the front area;
wherein, a voltage source VDD is disposed in the front area of the AMOLED body, according to the voltage drop generated by the power transmitting in the data transmission lines, use the voltage source VDD to compensate a voltage to the display device disposed in the AMOLED body from the terminal area of the AMOLED body to the front area of the AMOLED body gradually.

In the application, the AMOLED panel is also provided with:
a plurality of optical elements disposed above the AMOLED body between the front area and the terminal area;
a driving power structure disposed above the panel, and the driving power structure being electrically connected to each optical element respectively through data transmission lines, to drive the optical elements to emit light;
a compensating power structure disposed in the front area of the panel, being electrically connected to part of the optical elements, when the driving power structure drives the optical elements to operate, a voltage drop is generated in the data transmission lines, therefore the optical homogeneity of the AMOLED panel is improved by compensating a voltage to part of the optical elements.

In the application, at least one compensating power structure is disposed, to compensate a voltage to the areas with voltage drop in the panel.

Each optical element has a rated voltage, and the compensating voltages, which are generated by the compensating power structure and provided to the optical elements, change gradually along the direction extending from the front area to the terminal area, so that the each operating voltage of optical elements reaches the rated voltage.

In the application, the AMOLED body is also provided with an active area, and the compensating power structure electrically connects to each optical element respectively in condition that the metal wires encircles the active area. The panel is also provided with a gate power structure, the gate power structure electrically connects to the gate of each optical element respectively.

In the application, the AMOLED body is also provided with a flexible printed circuit, the flexible printed circuit is provided with a driving power connected to the driving power structure, a compensating power connected to the compensating power structure and a gate power connected to the gate power structures.

On such an AMOLED body, the difference generated by IR drop in different areas of the panel is compensated by adjusting the voltage source potential, to improve the optical homogeneity of the AMOLED panel.

The application further comprises a display device, the display device comprises the above-mentioned AMOLED panel.

The application further comprises a method for manufacturing the AMOLED panel, the method comprises:
providing an AMOLED body with a plurality of optical elements, the AMOLED body comprising a front area and a terminal area;
disposing a driving power structure in the front area of the AMOLED body, the driving power structure being connected to each optical element respectively, to drive the optical elements to emit light; and
disposing at least one compensating power structure in the terminal area of the

AMOLED body, and the compensating power structures being electrically connected to each optical element, to compensate a potential to part of the optical elements.

The above-mentioned method for manufacturing the AMOLED panel further comprises:
measuring optical characteristics of each area, and establishing optical characteristics data of each area of the AMOLED body, to compensate a potential according to the optical characteristics data of each area of the AMOLED body, wherein the optical characteristics data is established on the maximum value or the minimum value of the optical characteristics data of the panel, the optical characteristics comprise brightness, hue and chroma.

After establishing the optical characteristics data of the AMOLED body, analyze the data of each area, if the one of the optical characteristics data of the areas differ from the normal value greatly, compensate a potential to this area, so that the optical homogeneity of the AMOLED panel is improved.

The following will introduce combining with specific embodiments.

### Embodiment 1

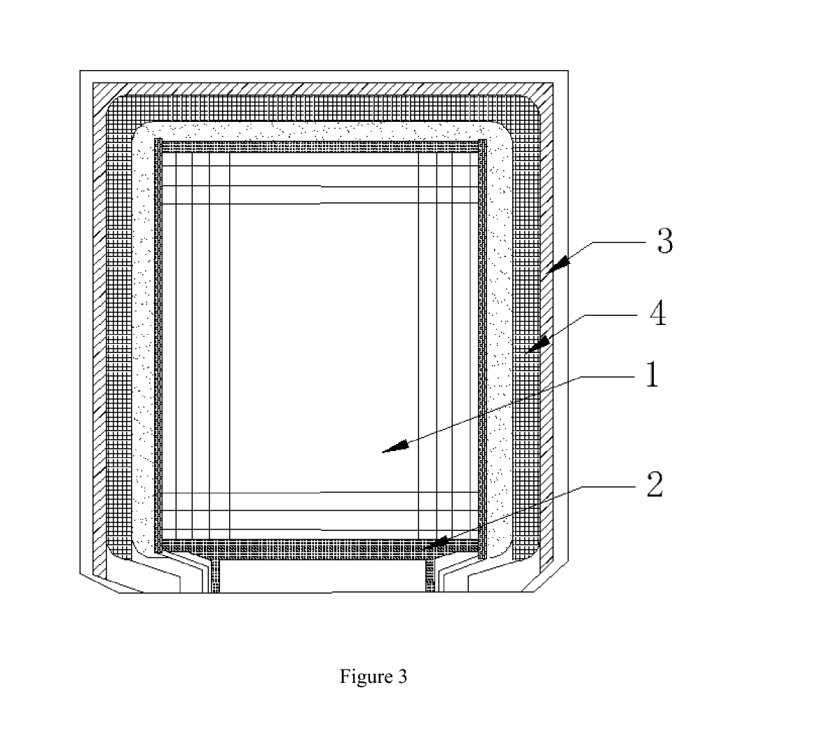

As shown in FIG. 3, an AMOLED panel comprises an AMOLED body 1, an driving power structure 2 and an compensating power structure 3. A plurality of optical elements are disposed above the AMOLED body 1. The driving power structure 2 electrically connects to each optical element through data transmission lines, to drive the optical elements to emit light; and the compensating power structure 3 electrically connects to part of the optical elements through data transmission lines, to compensate a voltage to the optical elements.

Set a front area and a terminal area opposite to the front area on the AMOLED body 1, if the optical elements of the panel are required to operate, add a voltage VDD in the front area of the AMOLED body, the voltage is transmitted to every optical element through data transmission lines, because the data transmission lines will generate certain IR drop, a voltage is compensated gradually from the terminal area of the AMOLED body to the front area of the AMOLED body.

A display device, based on the AMOLED body, is connected with a driving power, a compensating power and a gate power (not shown), wherein the driving power electrically connects to the driving power structure 2, the compensating power electrically connects to the compensating power structure 3, to provide a driving voltage. The panel is also provided with an active area and a gate power structure 4, and the compensating power electrically connects to each compensating power structure 3 respectively in condition that the metal wire encircles the active area, the gate power structure 4 electrically connects to the gate of each optical element respectively. The driving power, the compensating power and the gate power are connected to the AMOLED body through the flexible printed circuit disposed on the bottom of the AMOLED body.

Divide the voltage source potential of the AMOLED body into several areas, and set different voltage source potential according to different sizes and different areas, to improve the optical homogeneity of the AMOLED panel.

Connections between other devices of the AMOLED body are as same as connections between existing devices, therefore the description is omitted.

### Embodiment 2

Manufacture an AMOLED panel, firstly provide an AMOLED body provided with a plurality of optical elements, and then configure a driving power structure in the front area of the AMOLED body, wherein each driving power structure connects to each optical element respectively, to drive the optical elements to emit light, finally configure at least one compensating power structure in the terminal area of the AMOLED body, wherein the compensating power structure electrically connects to part of the optical elements respectively, to compensate a potential to the optical elements connected therefrom.

Provide a driving power connected to the driving power structure, to provide driving voltage to the driving power structure, and a compensating power electrically is connected to each compensating power structure, to provide driving voltage to the compensating power structure too.

After finishing the above-mentioned operations, measure optical characteristics of each area, then establish optical characteristics data of each area of the panel, and compensate a potential to the areas with insufficient potential according to the optical characteristics data, to reduce difference caused by IR drop between different areas, and improve the optical homogeneity of the AMOLED panel.

Wherein, the optical characteristics comprise brightness, hue and chroma generated by the panel.

The AMOLED panel, the manufacturing method thereof, the display device are designed and disclosed in the application. Therefore, by disposing a driving power structure and a compensating power structure on the panel, difference generated by IR drop in different positions of the panel can be compensated by the compensating power structure, thus the optical homogeneity of the AMOLED panel is increased, and the display quality of the AMOLED panel is improved greatly.

The foregoing is only the preferred embodiments of the application, not thus limiting embodiments and scope of the application, those skilled in the art should be able to realize that the schemes obtained from the content of specification and figures of the application are within the scope of the application.

What is claimed is:

1. An AMOLED panel, comprising:
an AMOLED body provided with a front area and a terminal area opposite to the front area;
a plurality of optical elements disposed above the AMOLED body between the front area and the terminal area; and
a compensating power structure disposed above the AMOLED body in the front area;
wherein, the compensating power structure electrically connects to each of the optical elements respectively, to be configured to improve optical homogeneity of the AMOLED panel by compensating a voltage to the optical elements.

2. The AMOLED panel according to claim 1, further comprising:
a driving power structure disposed above the AMOLED body;
data transmission lines disposed above the AMOLED body, and the driving power structure being connected to the optical elements through the data transmission lines, to drive each of the optical elements to operate;
wherein, a voltage drop is generated in the data transmission lines when the driving power structure drives the optical elements to operate, the compensating power structure compensates the voltage drop, to improve optical homogeneity of the AMOLED panel.

3. The AMOLED panel according to claim 2, wherein the optical elements have a rated voltage;
compensating voltages, which are generated by the compensating power structure and provided to the optical elements, increase gradually along a direction extending from the front area to the terminal area, so that each operating voltage of the optical elements reaches the rated voltage.

4. The AMOLED panel according to claim 3, wherein the AMOLED body is also provided with an active area, and the compensating power structure electrically connects to each of the optical elements respectively in condition that the metal wire encircles the active area.

5. The AMOLED panel according to claim 3, wherein the AMOLED body is also provided with a gate power structure, the gate power structure electrically connects to gate(s) of each of the optical elements respectively.

6. The AMOLED panel according to claim 5, wherein the AMOLED body is also provided with a flexible printed circuit, the flexible printed circuit is provided with a driving power connecting to the driving power structure, a compensating power connecting to the compensating power structure and a gate power connecting to the gate power structure.

7. A display device, comprising an AMOLED panel, the AMOLED panel comprising:
an AMOLED body provided with a front area and a terminal area opposite to the front area;
a plurality of optical elements disposed above the AMOLED body between the front area and the terminal area; and
a compensating power structure disposed above the AMOLED body in the front area;
wherein, the compensating power structure electrically connects to each of the optical elements respectively, to be configured to improve optical homogeneity of the AMOLED panel by compensating a voltage to the optical elements.

8. The display device according to claim 7, further comprises:
a driving power structure disposed above the AMOLED body;
data transmission lines disposed above the AMOLED body, and the driving power structure being connected to the optical elements through the data transmission lines, to drive each of the optical elements to operate;
wherein, a voltage drop is generated in the data transmission lines when the driving power structure drives the optical elements to operate, the compensating power structure compensates the voltage drop, to improve optical homogeneity of the AMOLED panel.

9. The display device according to claim 8, wherein the optical elements have a rated voltage;
compensating voltages, which are generated by the compensating power structure and provided to the optical elements, increase gradually along a direction extending from the front area to the terminal area, so that each operating voltage of the optical elements reaches the rated voltage.

10. The display device according to claim 9, wherein the AMOLED body is also provided with an active area, and the compensating power structure electrically connects to each of the optical elements respectively in condition that the metal wire encircles the active area.

11. The display device according to claim 9, wherein the AMOLED body is also provided with a gate power structure, the gate power structure electrically connects to gate(s) of each of the optical elements respectively.

12. The display device according to claim 11, wherein the AMOLED body is also provided with a flexible printed circuit, the flexible printed circuit is provided with a driving power connecting to the driving power structure, a compensating power connecting to the compensating power structure and a gate power connecting to the gate power structure.

13. A method for manufacturing an AMOLED panel, comprising:
providing an AMOLED body with a plurality of optical elements, the AMOLED body comprising a front area and a terminal area opposite to the front area;
disposing a driving power structure in the front area of the AMOLED body, the driving power structure being electrically connected to each of the optical elements respectively, to drive the optical elements to emit light; and
disposing at least one compensating power structure in the terminal area of the AMOLED body, the compensating power structure being electrically connected to each of the optical elements respectively, to compensate a potential to the optical elements.

14. The method according to claim 13, further comprises:
measuring optical characteristics of each area of the AMOLED body, and establishing an optical characteristics data of each area of the panel, to compensate a potential according to the optical characteristics data of each area of the AMOLED panel.

15. The method according to claim 14, wherein the optical characteristics comprise at least one of the following characteristics: brightness, hue and chroma.
